(19) United States
(12) Patent Application Publication
(10) Pub. No.: US 2026/0060025 A1
(43) Pub. Date: Feb. 26, 2026

(54) Wafer Transfer Device

(71) Applicant: Hitachi High-Tech Corporation, Minato-ku, Tokyo (JP)

(72) Inventors: Katsutoshi KOBAYASHI, Tokyo (JP); Akira NISHIOKA, Tokyo (JP); Tomokazu KOBAYASHI, Tokyo (JP); Masashi FUJITA, Tokyo (JP); Toshihiko SHIMIZU, Tokyo (JP); Itsuro SAWADA, Tokyo (JP)

(21) Appl. No.: 19/120,839

(22) PCT Filed: Nov. 7, 2022
(86) PCT No.: PCT/JP2022/041321

§ 371 Date: Apr. 14, 2025

(51) Int. Cl. H01L 21/67; H01L 21/677

(52) U.S. Cl. CPC H01L 21/67017; H01L 21/67196; H01L 21/67769

(57) ABSTRACT

To obtain a wafer transfer device that can suppress a rise in the temperature of the inside of a wafer transfer chamber by reducing a system resistance without changing the size of the wafer transfer chamber, the present invention provides a wafer transfer device including a wafer transfer chamber including a robot configured to transfer a wafer between a FOUP configured to house the wafer and a processing chamber configured to process the wafer, a door installed for a human to enter and exit from an inside of the wafer transfer chamber, and a fan and filter unit (FFU) chamber installed above the wafer transfer chamber and configured to feed inert gas into the wafer transfer chamber, a return flow passage for the inert gas being formed in a column constituting the wafer transfer chamber and being formed by hollowing the column, to make the FFU chamber and the wafer transfer chamber communicate with each other, and a duct being provided on the wafer transfer chamber side of the door and configured such that the inert gas in the wafer transfer chamber passes through the duct and flows into the FFU chamber when the door is in a closed state.

### TECHNICAL FIELD

The present invention relates to a wafer transfer device, and particularly relates to a wafer transfer device suitable for transferring a wafer stored in a FOUP to a processing chamber in a state in which the inside of a sealed and closed wafer transfer chamber is filled with inert gas by the inert gas being supplied from a fan and filter unit (which will hereinafter be referred to as an FFU) chamber in order to decrease oxygen concentration in the wafer transfer chamber.

### BACKGROUND ART

With the progress of a wafer microfabrication technology, an ultraclean environment in a wafer transfer chamber is desired to be achieved. In order to achieve this, an apparatus that seals the wafer transfer chamber and fills the wafer transfer chamber with inert gas has been developed, and patent applications for a related technology have been filed.

There is commonly used a circulating flow system in which inert gas is injected into an FFU chamber that is installed above the wafer transfer chamber and that includes an FFU, the inert gas is blown into the wafer transfer chamber by the FFU, flow passages for the inert gas to return to the FFU chamber are formed by hollowing columns constituting the wafer transfer chamber, and the inert gas blown into the wafer transfer chamber by the FFU is returned to the FFU chamber. In the following description, the return flow passages obtained by hollowing the columns constituting the wafer transfer chamber will be referred to as column return ducts.

Patent Documents 1 and 2 can be cited as prior art documents related to such a wafer transfer device.

In the foregoing Patent Document 1, it is described that, in a transfer chamber for delivering and receiving a wafer to and from a processing chamber side with use of a transfer robot in a casing, the casing includes a transfer space for housing the transfer robot, a gas processing space for housing a gas processing device, and a feedback space in which gas can be fed back from the transfer space to the gas processing space, the transfer space, the gas processing space, and the gas feedback space communicate with each other to thereby form one sealed space and constitute a circulation path, and the circulation path is provided with a plurality of fans to form a circulating flow.

In addition, the foregoing Patent Document 2 describes a substrate transfer apparatus including a ventilation unit driving chamber, a FOUP receiving chamber, a driving equipment chamber, and a ventilation duct, the ventilation unit driving chamber being provided with a fan for blowing air downward, the FOUP receiving chamber being disposed below the ventilation unit driving chamber and receiving a FOUP for storing a wafer, the driving equipment chamber being disposed below the FOUP receiving chamber, and the ventilation duct coupling the FOUP receiving chamber and the ventilation unit driving chamber to each other to circulate the air.

### PRIOR ART DOCUMENTS

### Patent Documents

Patent Document 1: JP-2021-7172-A
Patent Document 2: JP-2021-34724-A

### SUMMARY OF THE INVENTION

### Problems to be Solved by the Invention

In general, the FFU housing a fan motor is included in the wafer transfer chamber in a sealed state. A problem therefore occurs in that the motor of the FFU and other electric parts become a source of heat generation to raise the temperature of the inside of the wafer transfer chamber.

In order to suppress the rise in the temperature of the inside of the wafer transfer chamber, the power consumption of the FFU needs to be reduced by decreasing the rotational speed of the fan. The rotational speed of the fan depends on a system resistance determined by a fluid pressure loss that occurs when the inert gas is circulated through the wafer transfer chamber and the FFU chamber.

When this system resistance is reduced, the inert gas can be circulated by a fan having a low rotational speed. Thus, the power consumption of the FFU is reduced, so that a rise in the temperature of the inside of the wafer transfer chamber can be suppressed.

However, in order to reduce the system resistance, the speed of the inert gas flowing through the insides of the column return ducts described above needs to be decreased by enlarging the flow passage cross-sectional area of the column return ducts.

However, when the flow passage cross-sectional area of the column return ducts is increased, the column return ducts are enlarged, and thus the wafer transfer chamber is also correspondingly enlarged, which means the injection of a larger amount of inert gas. Expensive gas such as nitrogen gas is used as the inert gas in general. There are thus needs for suppressing the injected amount as much as possible.

Hence, in order to suppress a rise in the temperature of the inside of the wafer transfer chamber, the wafer transfer chamber is desired to be enlarged. Meanwhile, a problem of an increase in the injected amount of the inert gas occurs.

The present invention has been made in view of the above-described points. It is an object of the present invention to provide a wafer transfer device that can suppress a rise in the temperature of the inside of a wafer transfer chamber by reducing the system resistance without changing the size of the wafer transfer chamber.

### Means for Solving the Problems

In order to achieve the above object, a wafer transfer device according to the present invention includes a wafer transfer chamber including a robot configured to transfer a wafer between a FOUP configured to store the wafer and a processing chamber configured to process the wafer, a door installed for a human to enter and exit from an inside of the wafer transfer chamber, and a fan and filter unit (FFU) chamber installed above the wafer transfer chamber and configured to feed inert gas into the wafer transfer chamber, a return flow passage for the inert gas being formed in a column constituting the wafer transfer chamber and being formed by hollowing the column, to make the FFU chamber and the wafer transfer chamber communicate with each other, and a duct being provided on the wafer transfer chamber side of the door and configured such that the inert gas in the wafer transfer chamber passes through the duct and flows into the FFU chamber when the door is in a closed state.

### Advantages of the Invention

According to the present invention, it is possible to suppress a rise in the temperature of the inside of the wafer transfer chamber by reducing the system resistance without changing the size of the wafer transfer chamber.

### BRIEF DESCRIPTION OF THE DRAWINGS

FIG. 1 is a sectional view illustrating a general configuration of a first embodiment of a wafer transfer device according to the present invention.

FIG. 2 is a perspective view illustrating a wafer transfer chamber constituting the first embodiment of the wafer transfer device according to the present invention.

FIG. 3 is a perspective view illustrating an operation of opening a door installed on the wafer transfer chamber illustrated in FIG. 2.

FIG. 4 is a perspective view illustrating the wafer transfer chamber in a state in which the door having a duct in the first embodiment of the wafer transfer device according to the present invention installed thereon is opened.

FIG. 5 is a perspective view illustrating the wafer transfer chamber in a state in which an upper portion of an FFU chamber in the first embodiment of the wafer transfer device according to the present invention is cut.

FIG. 6 is a perspective view illustrating a wafer transfer chamber constituting a second embodiment of the wafer transfer device according to the present invention.

FIG. 7 is a perspective view illustrating a door return duct adopted in the second embodiment of the wafer transfer device according to the present invention.

FIG. 8 is a perspective view illustrating a door return duct adopted in a third embodiment of the wafer transfer device according to the present invention.

FIG. 9 is a perspective view illustrating the wafer transfer chamber in a state in which the door return duct in the first embodiment of the wafer transfer device according to the present invention is opened.

FIG. 10 is a perspective view illustrating a wafer transfer chamber in a state in which a door return duct as an example in a fourth embodiment of the wafer transfer device according to the present invention is opened.

FIG. 11 is a perspective view illustrating the wafer transfer chamber in a state in which the door return duct as another example in the fourth embodiment of the wafer transfer device according to the present invention is opened.

### MODES FOR CARRYING OUT THE INVENTION

A wafer transfer device according to the present invention will hereinafter be described on the basis of embodiments illustrated in the figure. Incidentally, in each embodiment, the same reference symbols are used for identical constituent parts.

### First Embodiment

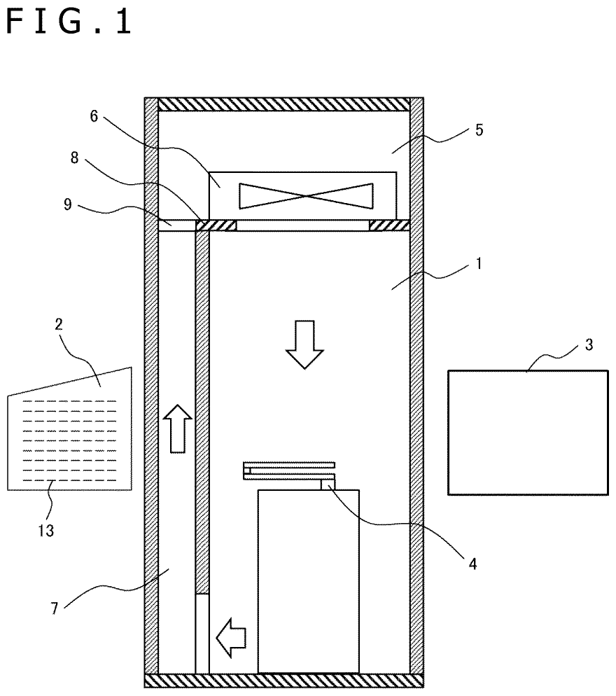

FIG. 1 illustrates a general configuration of a first embodiment of the wafer transfer device according to the present invention.

As illustrated in FIG. 1, the wafer transfer device according to the present embodiment substantially includes a wafer transfer chamber 1 including a robot 4 that transfers a wafer 13 between a FOUP 2 housing the wafer 13 and a processing chamber 3 for processing the wafer 13, and an FFU chamber 5 that is installed above the wafer transfer chamber 1 and that feeds inert gas into the wafer transfer chamber 1. In order to make the FFU chamber 5 and the wafer transfer chamber 1 communicate with each other, columns constituting the wafer transfer chamber 1 have inert gas return flow passages formed by hollowing the columns (parts of column return ducts 7 to be described later are the return flow passages).

Specifically, the robot 4 that draws out a wafer 13 housed in the FOUP 2 and transfers the wafer 13 to the processing chamber 3 for processing the wafer 13 is installed in the wafer transfer chamber 1. This robot 4 also plays a role of drawing out the wafer 13 that has been processed in the processing chamber 3 from the processing chamber 3 and returning the wafer 13 to the FOUP 2.

The FFU chamber 5 is present above the wafer transfer chamber 1. An FFU 6 including a fan for circulating the gas and a filter is present in the FFU chamber 5.

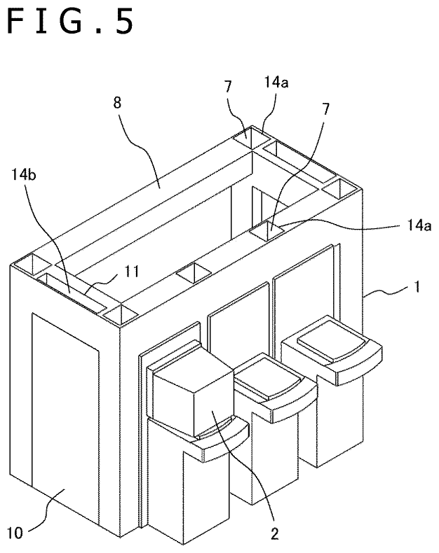

In order to fill the inside of the wafer transfer chamber 1 with the inert gas, the inert gas is injected into the FFU chamber 5, and the FFU 6 blows this inert gas into the wafer transfer chamber 1. The inert gas blown into the wafer transfer chamber 1 is blown into the FFU chamber 5 through the column return ducts 7 in which an air passage (return flow passage) for the inert gas to pass through is formed by hollowing the columns present in the wafer transfer chamber 1 (parts forming spaces at four corners of the wafer transfer chamber 1 in FIG. 5 to be described later and parts of long side portions which parts form spaces located between the parts forming the spaces at the four corners).

In addition, the FFU chamber 5 has an FFU chamber floor 8 for supporting the FFU 6, and the FFU chamber floor 8 has FFU chamber communication holes 9 formed to make the FFU chamber 5 and the column return ducts 7 communicate with each other.

A system in which the inert gas circulates through the wafer transfer chamber 1 and the FFU chamber 5 is thus constructed.

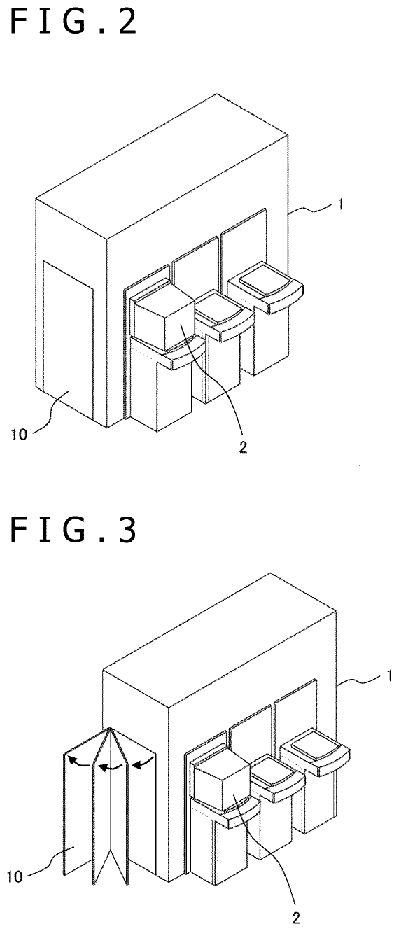

FIG. 2 illustrates a perspective view of the wafer transfer chamber 1 described above.

As illustrated in FIG. 2, the wafer transfer chamber 1 has a door 10 installed to allow a human to enter and exit from the inside of the wafer transfer chamber 1. This door 10 is of a rotary type. As illustrated in FIG. 3, the rotary type door 10 can be opened by being operated as indicated by arrows.

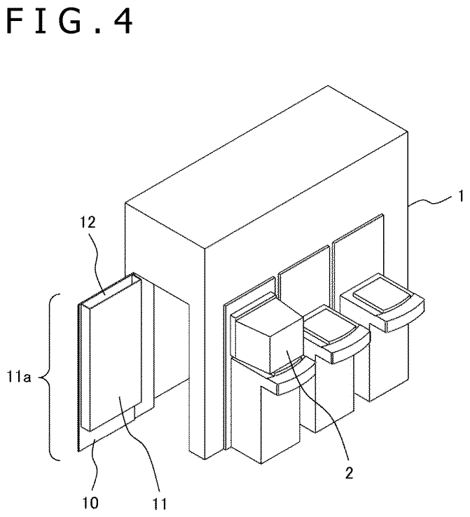

Moreover, in the present embodiment, as illustrated in FIG. 4, the wafer transfer chamber 1 side of the door 10 is provided with a duct 11, and the inert gas in the wafer transfer chamber 1 is configured to flow into the FFU chamber 5 through the duct 11 when the door 10 is in a closed state (see FIG. 5). A door as the above-described rotary type door 10 provided with the duct 11 will be referred to as a door return duct 11a. An air hole 12 for the inert gas to pass through is formed in the door return duct 11a.

FIG. 5 illustrates the wafer transfer chamber 1 in a state in which an upper portion of the FFU chamber 5 in the present embodiment is cut.

As illustrated in FIG. 5, in order to make the FFU chamber 5 and the column return ducts 7 communicate with each other, FFU chamber communication holes 14a of the column return ducts 7, the FFU chamber communication holes 14a communicating with the FFU chamber 5, are formed in the FFU chamber floor 8 that supports the FFU 6. Further, an FFU chamber communication hole 14b of the duct 11, the FFU chamber communication hole 14b communicating with the FFU chamber 5, is formed in the duct 11 to make the FFU chamber 5 and the door return duct 11a communicate with each other.

When the door 10 is closed, the sectional shape of an air passage of the door return duct 11a and the sectional shape of the FFU chamber communication hole 14b of the duct 11, the FFU chamber communication hole 14b communicating with the FFU chamber 5, substantially coincide with each other, and the inert gas can return to the FFU chamber 5 through the duct 11 and the FFU chamber communication hole 14b communicating with the FFU chamber 5. That is, a circulation system in which the inert gas flows through both the column return ducts 7 and the door return duct 11a and returns to the FFU chamber 5 can be constructed.

The wafer transfer chamber 1 is not enlarged by provision of the door return duct 11a. That is, the speed of the inert gas flowing through the column return ducts 7 can be reduced without a change in the size of the wafer transfer chamber 1. Thus, the system resistance is reduced, and the power consumption of the FFU 6 can be reduced.

The sectional shape of the FFU chamber communication hole 14b of the duct 11, the FFU chamber communication hole 14b communicating with the FFU chamber 5, and the sectional shape of the air passage of the door return duct 11a do not have to coincide with each other completely. It suffices to have parts overlapping each other and secure a cross section through which the inert gas can pass.

With such a configuration of the present embodiment, the wafer transfer chamber 1 is provided with the rotary type door 10 for a human to enter and exit from the inside of the wafer transfer chamber 1. The door 10 is provided with the duct 11, and the inert gas can thus pass through the inside of the duct 11. Further, the FFU chamber floor 8 for installing the FFU 6 is present at the bottom surface of the FFU chamber 5. The FFU chamber floor 8 divides the FFU chamber 5 and the wafer transfer chamber 1 from each other. In a case of the wafer transfer chamber 1 in a sealed state, the inert gas returns to the FFU chamber 5 through the column return ducts 7. Thus, the FFU chamber floor 8 that divides the FFU chamber 5 and the wafer transfer chamber 1 from each other is provided with the FFU chamber communication holes 14a at positions at which the column return ducts 7 are present. The FFU chamber communication holes 14a and the column return ducts 7 installed in a shape coinciding with that of the FFU chamber communication holes 14a enable the inert gas to return to the FFU chamber 5, and thus enable the inert gas to circulate between the FFU chamber 5 and the wafer transfer chamber 1.

In addition, in order to allow the inert gas to return to the FFU chamber 5 through the door return duct 11a, the FFU chamber communication hole 14b is provided at a position of the FFU chamber floor 8 dividing the FFU chamber 5 and the wafer transfer chamber 1 from each other at which position the door return duct 11a is located in a state in which the rotary type door 10 is closed.

Thus, the inert gas can return to the FFU chamber 5 through not only the column return ducts 7 but also the door return duct 11a, and the speed of the inert gas in each of the return ducts is reduced, so that the system resistance can be reduced.

Further, because of the structure in which the duct 11 is provided to the door 10, the system resistance can be reduced without a change in the size of the wafer transfer chamber 1.

### Second Embodiment

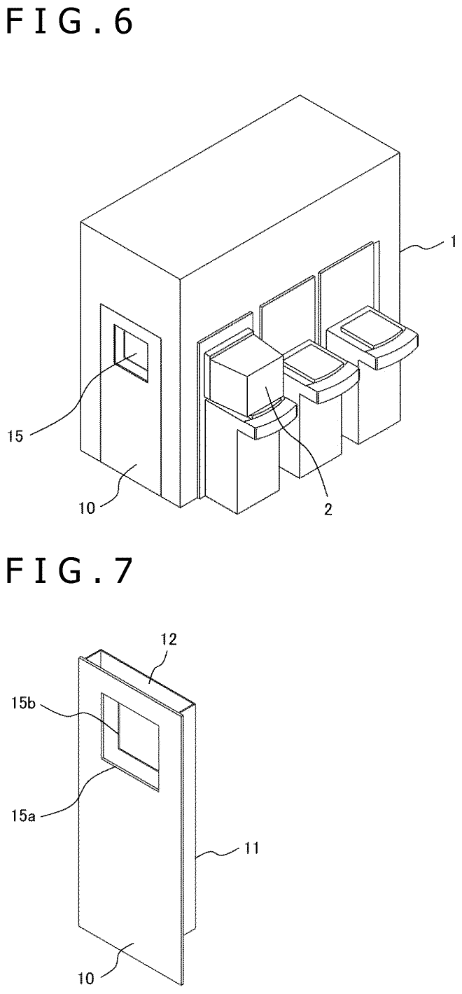

FIG. 6 and FIG. 7 illustrate a second embodiment of the wafer transfer device according to the present invention.

As illustrated in FIG. 6, in the present embodiment, in order to view the inside of the wafer transfer chamber 1 from the outside of the wafer transfer chamber 1, an observation window 15 that allows the inside of the wafer transfer chamber 1 to be observed is installed in the door 10 (door return duct 11a) and the duct 11.

Specifically, the door 10 (door return duct 11a) side is provided with a door side observation window 15a, and the duct 11 side is provided with a duct side observation window 15b. A transparent acrylic material, a glass material, or the like is used for parts of the door side observation window 15a and the duct side observation window 15b.

Needless to say, even such a configuration of the present embodiment can provide advantages similar to those of the first embodiment, and the inside of the wafer transfer chamber 1 can be observed from the outside of the wafer transfer chamber 1.

### Third Embodiment

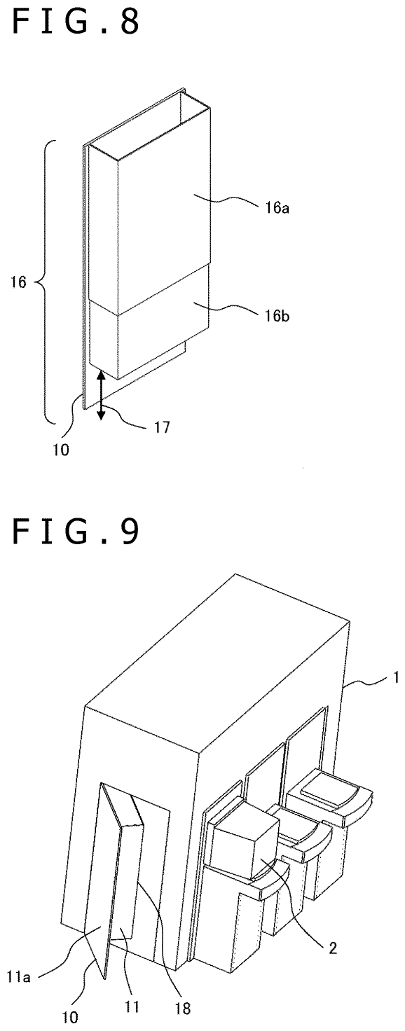

FIG. 8 illustrates a third embodiment of the wafer transfer device according to the present invention.

In the present embodiment illustrated in the figure, a door return duct 16 is configured such that the height of an inlet hole for the inert gas to enter the air passage of the duct 11 is adjustable.

Specifically, the duct 11 installed on the door 10 includes an outer duct 16a and an inner duct 16b. The outer duct 16a is fixed to the door 10. The inner duct 16b is configured to be slidable in an upward-downward direction with respect to the outer duct 16a.

In general, the inert gas blown into the wafer transfer chamber 1 passes through the inlet hole illustrated in FIG. 8 (though not directly visible, the inlet hole is present in a lower portion of the inner duct 16b in FIG. 8), and flows through the air passage of the door return duct 16.

In the present embodiment, two ducts, that is, the outer duct 16a and the inner duct 16b, are attached to the door 10. Further, a structure in which the outer duct 16a is fixed to the door 10 and the inner duct 16b is manually slidable in the upward-downward direction with respect to the outer duct 16a is adopted, making it possible to change the dimension of an inlet hole height 17 (distance between a lower portion of the door 10 and a lower portion of the inner duct 16b).

As the dimension of the inlet hole height 17 is increased, the system resistance for circulating the inert gas can be reduced, but the speed of a flow in a downward direction in the wafer transfer chamber 1 is reduced in a region at a height position at which the wafer 13 is transferred from the FOUP 2 to the processing chamber 3, so that minute particles tend to adhere to the wafer 13.

In view of this, the structure in which the inner duct 16b can be slid in the upward-downward direction is adopted in the present embodiment, making it possible to, needless to say, obtain advantages similar to those of the first embodiment and to change the inlet hole height 17 while both the system resistance and the speed of the downward air flow are adjusted.

### Fourth Embodiment

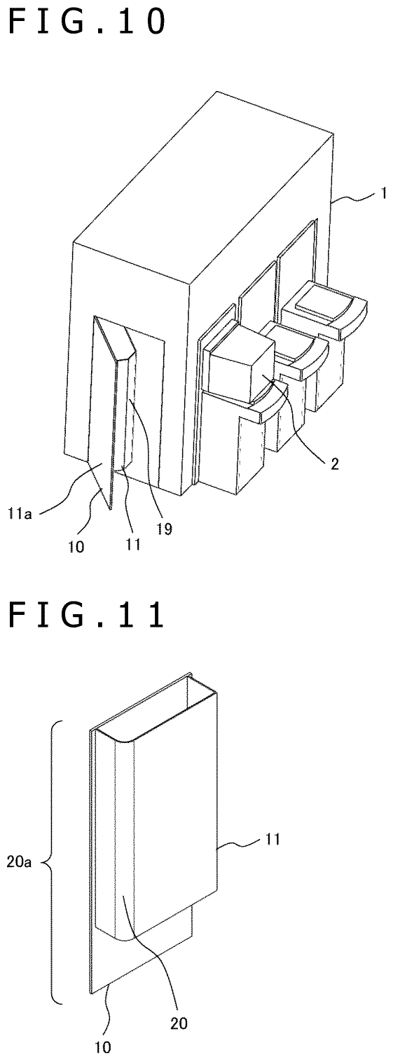

FIG. 10 and FIG. 11 illustrate a fourth embodiment of the wafer transfer device according to the present invention.

FIG. 9 illustrates a state in which the door 10 provided with the duct 11 in the foregoing first embodiment is opened.

In the configuration of the first embodiment illustrated in FIG. 9, in a case where the air passage of the door return duct 11a has a large flow passage sectional shape, there is a possibility of a duct angular portion 18 interfering with a wall and a column of the wafer transfer chamber 1 when the door 10 is opened or closed. Meanwhile, in order to reduce the system resistance as much as possible, there is a desire to enlarge the flow passage sectional shape of the air passage of the door return duct 11a as much as possible.

In view of this, in the present embodiment, as illustrated in FIG. 10, in order to prevent the interference of the duct angular portion 18 illustrated in FIG. 9 with a wall and a column of the wafer transfer chamber 1, the air passage formed in the duct 11 is constituted by a polygonal duct 19 formed by the duct angular portion 18 in FIG. 9 being cut and made to have a polygonal shape in cross section.

The flow passage sectional shape of the air passage of the door return duct 11a to which the polygonal duct 19 according to the present embodiment is attached is formed into a pentagonal shape as the polygonal shape.

In addition, the duct angular portion 18 illustrated in FIG. 9 may also have a desired streamlined shape illustrated in FIG. 11. That is, as illustrated in FIG. 11, a door return duct 20a provided with a streamline-shaped duct constituted by a streamlined duct 20 whose sectional shape is formed into a streamlined shape by the duct angular portion 18 being rounded is adopted for the air passage formed in the duct 11.

Needless to say, even such a configuration of the present embodiment can provide advantages similar to those of the first embodiment, and by installing a polygonal or streamlined duct with a high degree of shape freedom on the door 10, it is possible to prevent the interference of the duct with a wall and a column of the wafer transfer chamber 1 while securing a maximum flow passage cross-sectional area of the air passage.

It is to be noted that the present invention is not limited to the foregoing embodiments and includes various modifications. For example, the foregoing embodiments are described in detail to describe the present invention in an easily understandable manner, and are not necessarily limited to embodiments including all of the described configurations. In addition, a part of a configuration of a certain embodiment can be replaced with a configuration of another embodiment, and a configuration of a certain embodiment can be added to a configuration of another embodiment. In addition, for a part of a configuration of each embodiment, another configuration can be added, deleted, or substituted.

### DESCRIPTION OF REFERENCE SYMBOLS

1: Wafer transfer chamber
2: FOUP
3: Processing chamber
4: Robot
5: FFU (fan and filter unit) chamber
6: FFU
7: Column return duct
8: FFU chamber floor
9: FFU chamber communication hole
10: Door
11: Duct
11a, 16: Door return duct
12: Air hole
13: Wafer
14a: FFU chamber communication hole of the column return duct, the FFU chamber communication hole communicating with the FFU chamber
14b: FFU chamber communication hole of the duct, the FFU chamber communication hole communicating with the FFU chamber
15: Observation window
15a: Door side observation window
15b: Duct side observation window
16a: Outer duct
16b: Inner duct
17: Inlet hole height
18: Duct angular portion
19: Polygonal duct
20: Streamlined duct
20a: Door return duct provided with a streamline-shaped duct

1. A wafer transfer device comprising:
a wafer transfer chamber including a robot configured to transfer a wafer between a FOUP configured to house the wafer and a processing chamber configured to process the wafer;
a door installed for a human to enter and exit from an inside of the wafer transfer chamber; and
a fan and filter unit (FFU) chamber installed above the wafer transfer chamber and configured to feed inert gas into the wafer transfer chamber,
a return flow passage for the inert gas being formed in a column constituting the wafer transfer chamber and being formed by hollowing the column, to make the FFU chamber and the wafer transfer chamber communicate with each other, and
a duct being provided on the wafer transfer chamber side of the door and configured such that the inert gas in the wafer transfer chamber passes through the duct and flows into the FFU chamber when the door is in a closed state.

2. The wafer transfer device according to claim 1, wherein
the inert gas in the wafer transfer chamber passes through a column return duct as the return flow passage for the inert gas, the return flow passage being formed by hollowing the column.

3. The wafer transfer device according to claim 2, wherein
the FFU chamber has an FFU chamber floor for supporting the fan and filter unit (FFU), and an FFU chamber communication hole for making the FFU chamber and the column return duct communicate with each other is formed in the FFU chamber floor.

4. The wafer transfer device according to claim 3, wherein
the door is of a rotary type, and an air hole for the inert gas to pass through is formed in a door return duct having the duct on the door.

5. The wafer transfer device according to claim 4, wherein
a communication hole of the column return duct, the communication hole communicating with the FFU chamber, is formed in the FFU chamber floor to make the FFU chamber and the column return duct communicate with each other, and a communication hole of the duct, the communication hole communicating with the FFU chamber, is formed in the door return duct to make the FFU chamber and the door return duct communicate with each other.

6. The wafer transfer device according to claim 5, wherein
a sectional shape of an air passage of the door return duct and a sectional shape of the communication hole of the duct, the communication hole communicating with the FFU chamber, substantially coincide with each other when the door

7. The wafer transfer device according to claim 1, wherein
an observation window that allows the inside of the wafer transfer chamber to be observed is installed in the door and the duct.

8. The wafer transfer device according to claim 4, wherein
the door return duct is configured such that a height of an inlet hole for the inert gas to enter an air passage of the duct is adjustable.

9. The wafer transfer device according to claim 8, wherein
the duct installed on the door includes an outer duct and an inner duct, the outer duct is fixed to the door, and the inner duct is configured to be slidable in an upward-downward direction with respect to the outer duct.

10. The wafer transfer device according to claim 1, wherein
a sectional shape of an air passage formed in the duct is a polygonal or streamlined shape.

11. The wafer transfer device according to claim 10, wherein
the sectional shape of the air passage formed in the duct is formed into a polygonal shape by an angular portion of the duct being cut, or the sectional shape of the air passage formed in the duct is formed into a streamlined shape by the angular portion of the duct being rounded.
